(19) United States
(12) Patent Application Publication
(10) Pub. No.: US 2015/0172573 A1
(43) Pub. Date: Jun. 18, 2015

(54) RESET NOISE REDUCTION WITH FEEDBACK

(71) Applicants: Yibing Michelle WANG, Temple City, CA (US); Tae-Yon LEE, Seoul (KR)

(72) Inventors: Yibing Michelle WANG, Temple City, CA (US); Tae-Yon LEE, Seoul (KR)

(21) Appl. No.: 14/481,460

(22) Filed: Sep. 9, 2014

Related U.S. Application Data
(60) Provisional application No. 61/916,551, filed on Dec. 16, 2013.

(51) Int. Cl. H04N 5/363; H01L 27/146; H04N 5/378

(52) U.S. Cl. CPC H04N 5/363; H04N 5/378; H01L 27/14643

(57) ABSTRACT

Provided are an imaging device implementing pseudo correlated double sampling (CDS), a pixel of the imaging device and a control method of the image device. The imaging device includes: a pixel array including a pixel, the pixel including a reset transistor to control a reset of the pixel, a row select transistor to control a selection of the pixel to be read out, and a photodiode configured to generate a current in response to incident light; a readout circuit configured to read out an output signal of the pixel, based on the detected incident light, via a pixel output line; a feedback loop configured to receive a voltage from the pixel output line and to apply a reset gate voltage to a gate terminal of the reset transistor based on the received voltage; and a controller configured to control an application of a row select signal to the row select transistor to select the pixel to be read out, and to selectively add an offset to the photodiode to prevent the pixel from being reset despite the reset gate voltage applied to the reset transistor.

### CROSS-REFERENCE TO RELATED APPLICATION

This application claims the benefit of U.S. Provisional Application No. 61/916,551, filed on Dec. 16, 2013 in the U.S. Patent and Trademark Office, the disclosure of which is incorporated herein by reference in its entirety.

### BACKGROUND

1. Field

Apparatuses and methods consistent with exemplary embodiments relate to reducing reset noise in an image sensor, and more particularly to reducing thermal noise with pseudo correlated double sampling (CDS) using feedback to a reset gate.

2. Description of the Related Art

A related art complementary metal-oxide-semiconductor (CMOS) imaging sensor typically includes an array of image sensing pixels. FIG. 1 illustrates a circuit diagram of a related art image sensing pixel 100, which is referred to as a 4T pixel because the pixel 100 includes four transistors. As shown in FIG. 1, the 4T pixel 100 also includes a photodetector PD, which generates a current in response to detecting incident light. The generated current is accumulated (or integrated) to generate a voltage, which is read out of the 4T pixel 100 as an output signal. To reset the pixel, a reset transistor RST is turned on. Furthermore, to start a new integration period, the reset transistor RST is turned off, thereby allowing the generated current to integrate. The integration period of a pixel corresponds to a period between resets of the pixel.

A major source of noise in the image sensing pixels is the reset transistor RST, which can exhibit reset noise such as flicker noise, thermal noise (i.e., kTC noise), and other types of noise. One related art technique to reduce reset noise in the 4T pixel is correlated double sampling (CDS). Generally, CDS is a method to measure an electrical value that allows removal of an undesired offset based on two output measurements, i.e., an output measurement in a known condition and an output measurement in an unknown condition. When used in a CMOS imaging sensor, CDS is a noise-reduction technique based on a difference between a reference voltage (i.e., reset voltage after the pixel is reset) and a signal voltage (i.e., the pixel's voltage at the end of integration) at the end of each integration period.

FIG. 2 illustrates an example timing diagram of the related art on-chip CDS. As an example, for on-chip CDS, the related art 4T pixel 100 has a general operation order including sample reset voltage, charge transfer, and sample signal voltage for each integration period. The sample reset and the signal sample have a correlated kTC component, while flicker noise may generally be high at low frequency only.

In detail, as shown in FIG. 2, the reset voltage Vrst corresponds to Vrst=Vr+Nktc+Nf(r), where Vr is the ideal reset voltage, Nktc is the correlated thermal noise component, and Nf(r) is the flicker noise component at the reset. Furthermore, the signal voltage Vsig corresponds to Vsig=Vr+Nktc+Nf(s)−Vlight, where Nf(s) is the flicker noise component at the signal sample and Vlight is the illuminance voltage, i.e., integrated voltage value corresponding to illuminance.

The correlated thermal noise component Nktc is canceled out by the difference between the signal voltage and the reset voltage: Vrst−Vsig=Vlight+Nf(r)−Nf(s). Moreover, when the time difference between the sample reset and the signal sample is short such that Nf(r)=Nf(s), the flicker noise components Nf(r) and Nf(s) can also be canceled by the difference between the signal voltage and the reset voltage, such that only the illuminance voltage Vlight is left.

For CMOS imaging sensors with 3T pixels, the on-chip CDS is not applicable. FIG. 3 illustrates a circuit diagram of a related art 3T pixel 300. In this case, a related art pseudo-CDS technique or a related art off-chip CDS technique can be used. FIG. 4 illustrates an example timing diagram of the related art pseudo-CDS and the related art off-chip CDS.

In the related art pseudo-CDS, the signal voltage is sampled and then the subsequent reset voltage for the next integration period is sampled and a difference therebetween is read out. However, this approach will not cancel or reduce the kTC noise. In detail, as shown in FIG. 4, the reset voltage Vrst(1) at pseudo-CDS readout interval (1) corresponds to Vrst(1)=Vr+Nktc(1)+Nf(r1), where Vr is the ideal reset voltage, Nktc(1) is the thermal noise component at the reset of a second integration period (1), and Nf(r1) is the flicker noise component at the reset in the readout interval (1). Furthermore, the signal voltage Vsig(1) at the particular readout interval (1) corresponds to Vsig(1)=Vr+Nktc(0)+Nf(s1)−Vlight, where Nktc(0) is the thermal noise component at the signal of a first integration period (0) preceding the abovementioned second integration period, Nf(s1) is the flicker noise component at the signal in the readout interval (1), and Vlight is the illuminance voltage.

Thus, using pseudo-CDS, the difference between the signal voltage and the reset voltage can cancel the flicker noise Nf, since Nf(1)=Nf(r1)=Nf(s1), but cannot cancel the thermal noise component since Nktc(0) and Nktc(1) of the different integration periods are not correlated: Vrst(1)−Vsig(1)=Vlight+Nktc(1)−Nktc(0).

Related art methods to cancel the reset noise utilize a feedback loop from a column feedback line to a reset transistor. FIG. 5 is a circuit diagram of a related art image sensing pixel that reduces reset thermal noise via feedback to reset gate (FRG). As illustrated in FIG. 5, a feedback voltage is generated from an operational amplifier, and provided to the reset transistor via a feedback loop. However, to prevent a reset of the pixel due to this feedback voltage to the reset transistor, an additional transistor is included between the feedback loop and the reset transistor. The source terminal of the additional transistor is connected to the feedback line, while the drain terminal is connected to the gate terminal of the reset transistor. Additionally, the gate terminal of the additional transistor is connected to a row select line, so as to turn on the additional transistor only when the pixel is selected for reading out. As such, an unintended pixel reset (i.e., when a pixel is not selected for reading out) due to the feedback voltage is prevented by turning on the additional transistor to conduct the feedback voltage to the reset gate only when the pixel is selected to be read out. However, the related art image sensing pixel that implements FRG increases the area of the pixel as a result of the additional transistor.

FIG. 6 is a circuit diagram of a related art image sensing pixel that reduces reset thermal noise via feedback to reset drain (FRD). As shown in FIG. 6, the gate terminal of the reset transistor is connected to a reset line that applies a reset voltage to turn on the transistor only when the pixel is intended to be reset. However, while this configuration does not result in an area increase due to an additional transistor (as is the case in the related art image sensing pixel of FIG. 5), bandwidth control is crucial to ensure that the feedback loop is stable and high frequency noise is not amplified.

### SUMMARY

Aspects of one or more exemplary embodiments relate to methods and apparatuses for reducing thermal noise in CMOS imaging sensors. Furthermore, aspects of one or more exemplary embodiments relate to methods and apparatuses for reducing thermal noise in CMOS imaging sensors utilizing pseudo-CDS for pixel readouts. Additionally, aspects of one or more exemplary embodiments relate to methods and apparatuses for reducing thermal noise in CMOS imaging sensors using feedback to a reset gate (FRG) without the inclusion of an additional transistor.

According to an aspect of an exemplary embodiment, there is provided an imaging device implementing pseudo correlated double sampling (CDS) for pixel readouts, the imaging device including: a pixel array including a pixel, the pixel including a reset transistor to control a reset of the pixel, a row select transistor to control a selection of the pixel to be read out, and a photodiode configured to generate a current in response to incident light; a readout circuit configured to read out an output signal of the pixel, based on the detected incident light, via a pixel output line; a feedback loop configured to receive a voltage from the pixel output line and to apply a reset gate voltage to a gate terminal of the reset transistor based on the received voltage; and a controller configured to control an application of a row select signal to the row select transistor to select the pixel to be read out, and to selectively add an offset to the photodiode to prevent the pixel from being reset despite the reset gate voltage applied to the reset transistor.

The pixel may be a 3T pixel, or a pixel that uses a pseudo-CDS readout.

The controller may be configured to control an application of a signal, inverse to the row select signal, to the pixel to selectively add the offset to the photodiode.

When the pixel is not selected to be read out, the controller may be configured to apply the row select signal having a first state to turn off the row select transistor, and to apply the signal having a second state, inverse to the first state, to the pixel to prevent the pixel from being reset, and when the pixel is selected to be read out, the controller may be configured to apply the row select signal having the second state to turn on the row select transistor, and to apply the signal, having the first state, to the pixel to allow the pixel to be reset.

The pixel may further include a capacitor, wherein the controller may be configured to control the application of the signal, via a signal line, to a bottom plate of the capacitor to selectively add the offset to the photodiode.

The capacitor may be arranged parallel to the photodiode.

The pixel further may further include a pixel output transistor and a node, the photodiode may be connected to a drain terminal of the reset transistor through the node and may be connected to a gate terminal of the pixel output transistor via the node, a source terminal of the reset transistor may be connected to a reference voltage line, and a drain terminal of the row select transistor may be connected to a source terminal of the pixel output transistor, a gate terminal of the row select transistor may be configured to receive the row select signal, and a source terminal of the row select transistor may be connected to the pixel output line.

A top plate of the capacitor may be connected to the node, and the signal line may not be connected to the photodiode.

The row select transistor may be connected to the feedback loop without an additional transistor between the feedback loop and the gate terminal of the row select transistor.

The feedback loop may include an operational amplifier including a first input terminal configured to receive a reference voltage and a second input terminal configured to receive the voltage from the pixel output line, and the operational amplifier may output the reset gate voltage according to a comparison between the reference voltage and the voltage from the pixel output line.

The pixel array may be a complementary metal-oxide-semiconductor (CMOS) image sensor pixel array.

According to an aspect of another exemplary embodiment, there is provided a pixel of an imaging device, the pixel including: a photodiode configured to generate a current in response to incident light; a reset transistor configured to control a reset of the pixel; and a row select transistor configured to control a selection of the pixel to be read out according to a row select signal and to output an output signal of the pixel, based on the incident light, wherein a gate terminal of the reset transistor is configured to receive a reset gate voltage generated based on the output signal, and wherein the gate terminal of the reset transistor receives the reset gate voltage without an additional transistor between the gate terminal of the reset transistor and a feedback point from which the pixel receives the reset gate voltage.

The pixel may receive a signal to selectively add an offset to the photodiode to prevent the pixel from being reset despite the reset gate voltage applied to the gate terminal of the reset transistor.

The signal received by the pixel may be inverse to the row select signal.

The pixel may further include a capacitor connected to a signal line to receive the signal for selectively adding the offset to the photodiode.

The pixel may further include: a pixel output transistor connected to the reset transistor and the row select transistor; and a node, wherein the photodiode may be connected to a drain terminal of the reset transistor through the node and may be connected to a gate terminal of the pixel output transistor via the node, a source terminal of the reset transistor may be connected to a reference voltage line, and a drain terminal of the row select transistor may be connected to a source terminal of the pixel output transistor, and a gate terminal of the row select transistor may be configured to receive the row select signal.

A bottom plate of the capacitor may be connected to the signal line and a top plate of the capacitor is connected to the node, and the photodiode may not be connected to the signal line.

According to an aspect of another exemplary embodiment, there is provided a control method of an imaging device implementing pseudo-CDS for pixel readouts, the method including: controlling to apply a reset gate voltage to a gate terminal of a reset transistor, the reset gate voltage being based on a feedback from an output of a pixel including the reset transistor, a row select transistor, and a photodiode; and controlling to selectively add an offset to the photodiode to prevent a reset of the pixel despite the reset gate voltage.

The controlling may include: in response to the pixel not being selected for reading out, controlling to apply a first signal having a first state to a gate terminal of the row select transistor, and to apply a second signal having a second state, inverse to the first state, to the pixel to add the offset to the photodiode to prevent the reset of the pixel despite the reset gate voltage; and in response to the pixel being selected for reading out, controlling to apply the first signal having the second state to the gate terminal of the row select transistor to turn on the row select transistor, and to apply the second signal having the first state to the pixel to allow the pixel to be reset.

According to an aspect of another exemplary embodiment, there is provided a computer-readable recording medium having recorded thereon a program executable by a computer for performing the control method.

### BRIEF DESCRIPTION OF THE DRAWINGS

The above and/or other aspects will be more apparent by describing exemplary embodiments with reference to the accompanying drawings, in which:

FIG. 1 is a circuit diagram of a related art image sensing 4T pixel;

FIG. 2 is an example timing diagram of a related art on-chip CDS;

FIG. 3 is a circuit diagram of a related art image sensing 3T pixel;

FIG. 4 is an example timing diagram of a related art pseudo-CDS;

FIG. 5 is a diagram of a related art image sensing pixel that reduces reset thermal noise via feedback to reset gate (FRG);

FIG. 6 is a circuit diagram of a related art image sensing pixel that reduces reset thermal noise via feedback to reset drain (FRD);

FIG. 7 is a block diagram of an imaging device according to an exemplary embodiment;

FIG. 8 is a circuit diagram of an imaging sensor according to an exemplary embodiment;

FIG. 9 is a circuit diagram of an imaging sensor according to another exemplary embodiment; and

FIG. 10 is a flowchart of an image sensing method according to an exemplary embodiment.

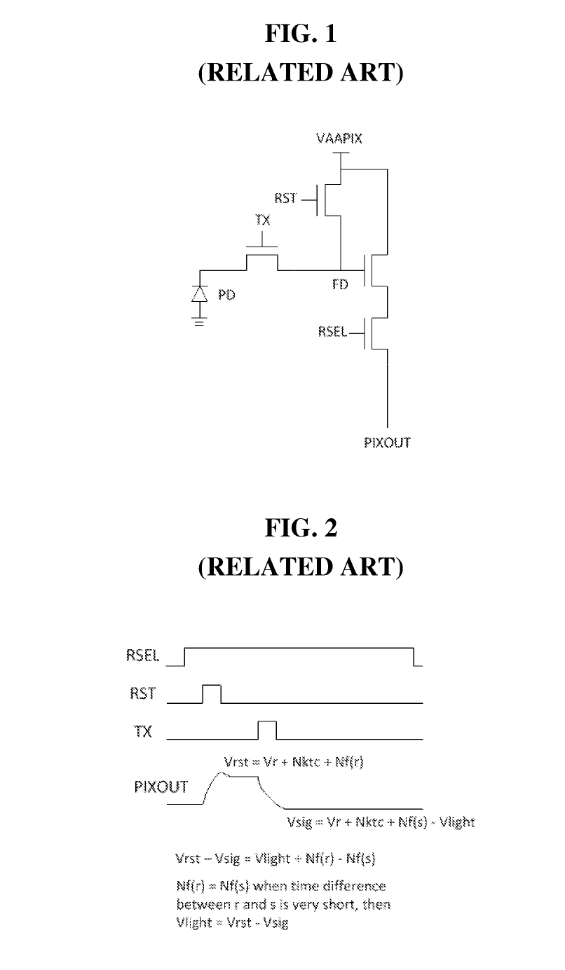

### DETAILED DESCRIPTION OF EXEMPLARY EMBODIMENTS

Certain exemplary embodiments are described in higher detail below with reference to the accompanying drawings.

In the following description, like drawing reference numerals are used for the like elements, even in different drawings. The matters defined in the description, such as detailed construction and elements, are provided to assist in a comprehensive understanding of exemplary embodiments. However, exemplary embodiments can be practiced without those specifically defined matters. Also, well-known functions or constructions are not described in detail since they would obscure the application with unnecessary detail.

According to aspects of one of more exemplary embodiments, a feedback voltage is applied to a reset gate to reduce a thermal noise component of a pseudo-CDS output. Additionally, according to aspects of one or more exemplary embodiments, an unintended reset of a pixel is prevented by selectively introducing an offset to a photodiode of the pixel.

In further detail, according to aspects of one or more exemplary embodiments, a feedback loop to control a reset gate voltage in a CMOS imaging sensor is used to reduce thermal noise, without the need for an additional transistor in a pixel. In particular, the thermal noise can be reduced by the gain of an operational amplifier in the feedback loop. Furthermore, to reset one row of a pixel matrix at a time without the inclusion of an additional transistor, an offset is selectively introduced. Namely, for rows that are not selected for reading out, an offset is added to photodiodes of pixels to prevent them from being reset despite the reset gate voltage. Conversely, for a row that is selected, no offset is added thereby allowing the reset.

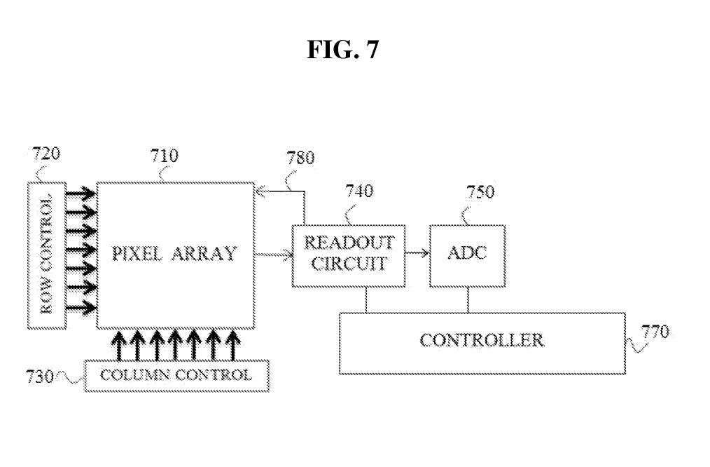

FIG. 7 is a block diagram of an imaging device according to an exemplary embodiment. By way of example, the imaging device may be a CMOS imaging sensor, and may be included in any device including an image capturing device such as a camera, a mobile phone, a tablet, a personal computer, etc. Referring to FIG. 7, the imaging device includes a pixel array 710, a row control 720, a column control 730, a readout circuit 740, one or more analog-to-digital converters (ADC) 750, and a controller 770. The imaging device additionally includes a feedback loop 780 to reduce a thermal noise component associated with pseudo-CDS sampling. The imaging device may include additional components in one or more other exemplary embodiments, such as one or more amplifiers, memory, control logic, a reference voltage and current generator, a phase lock loop, an image and signal processing unit, a parallel and/or serial interface, etc.

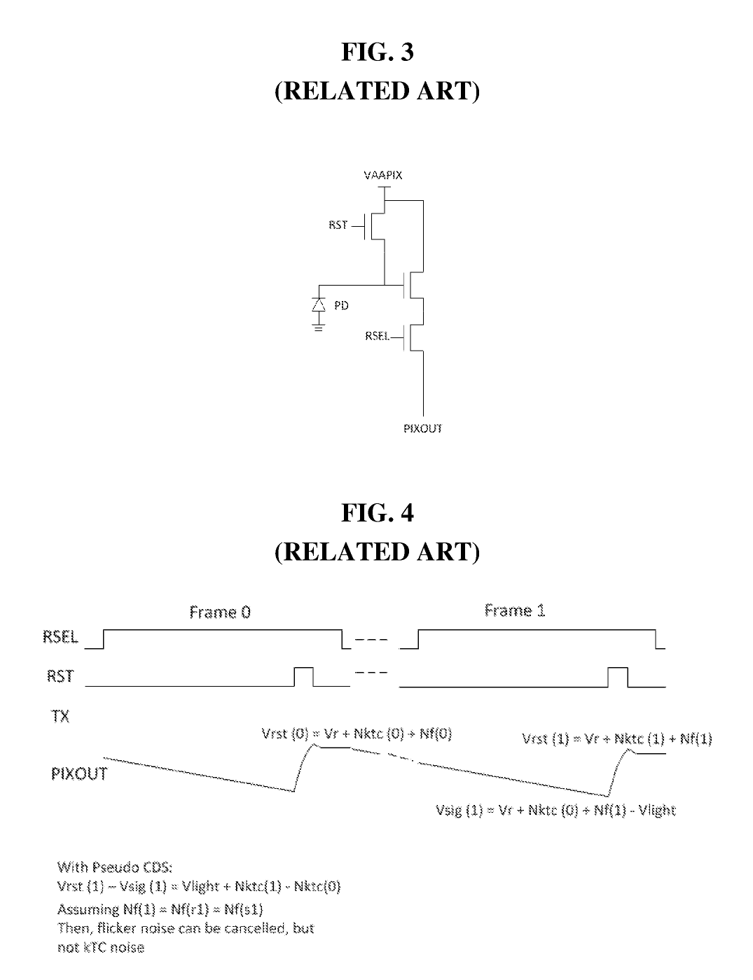

The pixel array 710 includes rows and columns of image sensing pixels that are configured to generate a current in response to detecting incident light. The generated current is accumulated (or integrated) to generate a voltage as an output signal. In the present exemplary embodiment, the image sensing pixels may be 3T pixels (such as shown in FIG. 3), although it is understood that one or more exemplary embodiments are not limited thereto.

The row control 720 is configured to control which row of the pixel array 710 will be read out at a certain readout interval, and the column control 730 is configured to control which column of the pixel array 710 will be read out at a certain readout interval.

The readout circuit 740 is configured to read out, implementing pseudo-CDS, an output signal in each of the pixels according to controls of the row control 720 and the column control 730. For example, the readout circuit 720 may be a column readout circuit. In detail, for a particular readout interval, the readout circuit 740 is configured to sample a signal voltage of the pixel and to sample a subsequent reset voltage of the pixel and output a difference therebetween.

The one or more ADCs 750 are configured to digitize the pseudo-CDS output of each pixel from the readout circuit 740.

The controller 770 is configured to control the readout circuit 740 to read out an output signal of a pixel for every integration period (i.e., corresponding to every shutter reset). That is, the controller 770 is configured to control the readout circuit 740 such that any time that the pixel is reset, the readout circuit 740 samples a signal voltage of the pixel and a subsequent reset voltage of the pixel and outputs a difference therebetween. Additionally, the controller 770 is configured to control an application of row select signals to the pixels of the pixel array 710, thereby controlling an addition of an offset to the photodiodes of the pixel array 710.

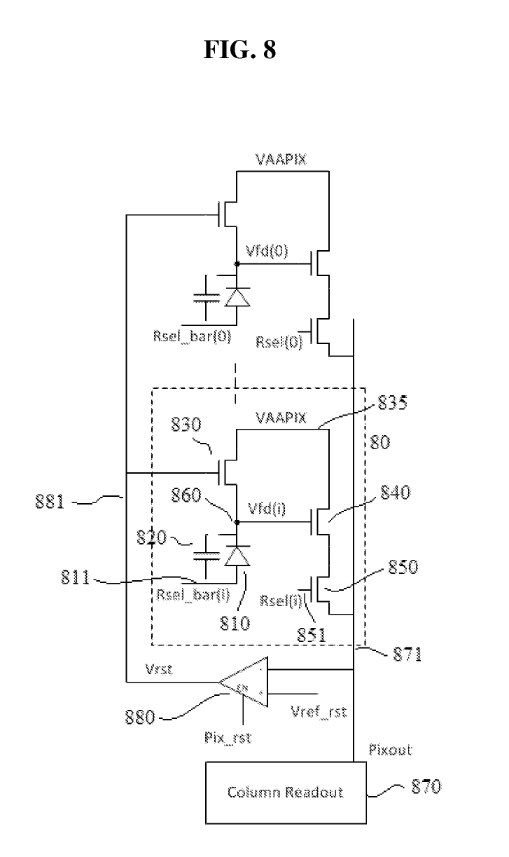

The feedback loop 780 outputs a feedback voltage per column from the readout circuit 740 to gate terminals of reset transistors in the pixel array. For example, as will be described in detail below with reference to FIG. 8, the feedback loop 780 may include an operational amplifier that outputs the feedback voltage according to a comparison between a reference voltage and a voltage input from the readout circuit 740.

FIG. 8 is a circuit diagram of an imaging sensor including an active pixel 80, a column readout circuit 870, an operational amplifier (op-amp) 880, and a feedback line 881 according to an exemplary embodiment. The column readout circuit 870 may correspond to the readout circuit 740 illustrated in FIG. 7, and the op-amp 880 and feedback line 881 may correspond to the feedback loop 780 illustrated in FIG. 7. Referring to FIG. 8, the active pixel 80 includes a photodiode 810, a capacitor 820, a reset transistor 830, a source follower transistor 840, a row select transistor 850, and a floating diffusion node 860. In the present exemplary embodiment, the photodiode 810 may be a silicon photodiode or an organic photodiode. It is understood that one or more exemplary embodiments are not limited to this combination of elements, and may include fewer elements and/or additional elements. For example, according to another exemplary embodiment, the capacitor 820 may be omitted.

The photodiode 810 is configured to generate a current in response to detecting incident light. By way of example, the photodiode 810 may include a p-n junction in which the p-doped side is connected to a second row select signal line 811 through which a second row select signal Rsel_bar(i) is applied, and the n-doped side is connected via the floating diffusion node 860 to the drain terminal of the reset transistor 830 and the gate terminal of the source follower transistor 840. In this case, when the photodiode is exposed to optical radiation (i.e., illumination), electrons flow from the p-doped side to the n-doped side.

The capacitor 820 is disposed such that a bottom plate of the capacitor 820 is connected to the second row select signal line 811 through which the second row select signal Rsel_bar(i) is applied, and is connected to the exposed side (e.g., p-doped side) of the photodiode 810. In this case, the capacitor 820 may be arranged parallel to the photodiode 810, or may be omitted, e.g., may be simply a parasitic capacitance of the photodiode itself.

The gate terminal of the reset transistor 830 is connected to the feedback line 881, while the source terminal of the reset transistor 830 is connected to a reference voltage line 835. As such, the reset gate voltage during pixel reset is controlled using the feedback loop 710. For example, when a positive reset voltage is applied to the gate terminal of the reset transistor 830 via the feedback loop 710, the reset transistor 830 is turned on and the node 860 is set to a reset voltage such that the pixel output line 871 has the same voltage as that of Vref_rst.

The source follower transistor 840 buffers the voltage of the node 860 to the pixel output line 871. As stated above, the gate terminal of the source follower transistor 840 is connected to the photodiode 810 via the floating diffusion node 860.

The drain terminal of the row select transistor 850 is connected to the source terminal of the source follower transistor 840 to select a certain row of pixels for output. Furthermore, the gate terminal of the row select transistor 850 is connected to a first row select signal line 851 from which a first row select signal Rsel(i) is applied. When a particular row in which the active pixel 80 is disposed is selected for reading out, the first row select signal is applied to turn on the row select transistor 850 (e.g., the first row select signal Rsel(i) has a high state). In this case, the pixel voltage is read out by the column readout circuit 870 via the pixel output line 871. The pixel output line 871 connects the source terminal of the row select transistor 850 to the column readout circuit 870 and the op-amp 880.

The CMOS imaging sensor according to the present exemplary embodiment uses the feedback line 881 and the op-amp 880 (e.g., comparator) to control a reset gate voltage and thereby reduce kTC noise by the gain of the op-amp 880. The op-amp 880 includes a positive terminal connected to a reference voltage line and a negative terminal connected to the pixel output line 871. The op-amp 880 outputs a voltage according to a comparison between a reference voltage Vref_rst input to the positive terminal and a voltage input from the pixel output line 871 to the negative terminal. This output voltage is applied as the reset gate voltage to the gate terminal of the reset transistor 830. Assume the gain of the feedback amplifier, the noise power at the photodiode of the pixel can be expressed as:

$$\overline{{v}_{n , pd}^{2} ( f )} = {\vert \frac{{G}_{RSTG} ( f )}{1 + {G}_{AMP} ( f ) \cdot {G}_{RSTD} ( f ) \cdot {G}_{SF} ( f )} \vert}^{2} \cdot \overline{{v}_{n , r}^{2} ( f )} + {\vert \frac{{G}_{AMP} ( f ) \cdot {G}_{RSTD} ( f )}{1 + {G}_{AMP} ( f ) \cdot {G}_{RSTD} ( f ) \cdot {G}_{SF} ( f )} \vert}^{2} \cdot \overline{{v}_{n , amp}^{2} ( f )} ,$$

where G_{SF}, G_{AMP} and G_{RSTG} and G_{RSTD} are the gain of the source follower, amplifier, the gain of the reset transistor from gate to source, and the gain of reset transistor from drain to source, v̅_̅{̅n̅,̅r̅}̅²̅(̅f̅)̅ is the reset kTC noise, v̅_̅{̅n̅,̅a̅m̅p̅}̅²̅(̅f̅)̅ is the input-referred noise of the feedback amplifier. In this case, the kTC noise is reduced mainly by the amplifier gain, and the higher the gain is, the greater noise reduction is.

Meanwhile, to reset one row of the pixel array 710 at a time despite the reset gate voltage applied to all the gate terminal of the reset transistor 830 in the same column, the active pixel 80 according to the present exemplary embodiment does not require an additional transistor. Rather, the reset is controlled by an offset selectively introduced to the photodiode 810. Specifically, for rows that are not selected for reading out, the offset is added to the photodiodes 810 to prevent the photodiodes 810 from being reset despite the reset gate voltage. Conversely, for the row that is selected, no offset is added, thereby allowing the reset. The selective introduction of the offset is controlled by the second row select signal Rsel_bar(i), which may be the inverse of the first row select signal Rsel(i).

In further detail, and as set forth above, when a particular row (i) in which the active pixel 80 is disposed is selected for reading out, the first row select signal Rsel(i) is applied to turn on the row select transistor 850 (e.g., the first row select signal Rsel(i) has a high state). Additionally, according to the present exemplary embodiment, when the particular row is selected for reading out, the second row select signal Rsel_bar(i) is applied to the bottom plate of the capacitor 820 in the same row so as to not add the offset to the photodiode 810 (e.g., the second row select signal Rsel_bar(i) has a low state). Thus, in this case, the active pixel 80 is allowed to be reset according to the reset gate voltage applied to the reset transistor 830 from the feedback loop 810.

Meanwhile, when the particular row (i) in which the active pixel 80 is disposed is not selected for reading out, the first row select signal Rsel(i) is applied to turn off the row select transistor 850 (e.g., the first row select signal Rsel(i) has a low state). Additionally, according to the present exemplary embodiment, when the particular row is not selected for reading out, the second row select signal Rsel_bar(i) is applied to the bottom plate of the capacitor 820 so as to add the offset to the photodiode 810 (e.g., the second row select signal Rsel_bar(i) has a high state). Thus, in this case, the active pixel 80 is prevented from being reset despite the reset gate voltage applied to the reset transistor 830 from the feedback loop 710. That is, the second row select signal Rsel_bar(i) is applied to the bottom plate of the capacitor 820 to thereby add an offset to the photodiode 810. Accordingly, the second row select signal Rsel_bar(i) applied via the second row select signal line 811 prevents the non-selected pixels from being reset even when the reset gate voltage is high.

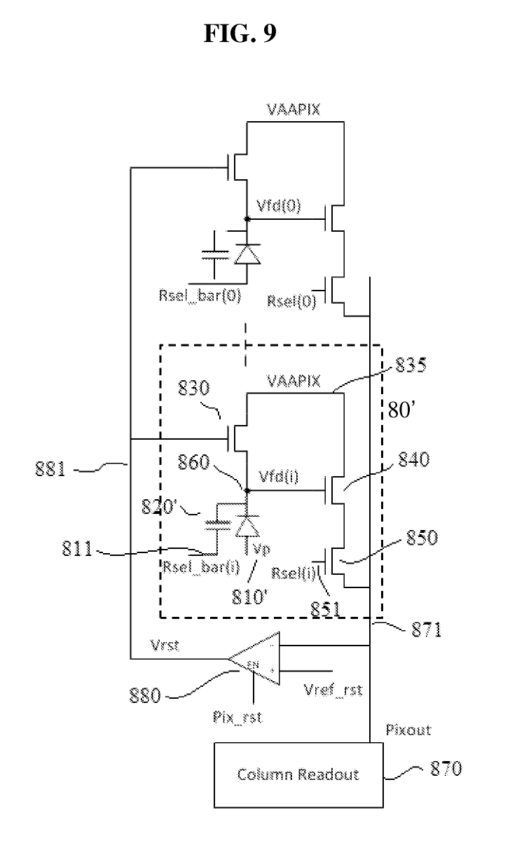

FIG. 9 is a circuit diagram of an imaging sensor including an active pixel 80′, a column readout circuit 870, an op-amp 880, and a feedback line 881 according to another exemplary embodiment. Referring to FIG. 9, the active pixel 80′ includes a photodiode 810′, a capacitor 820′, a reset transistor 830, a charge sensing transistor 840, a row select transistor 850, and a floating diffusion node 860. As the op-amp 880, the feedback line 881, the reset transistor 830, the charge sensing transistor 840, the row select transistor 850, and the floating diffusion node 860 according to the present exemplary embodiment are similar or substantially similar to those described above with reference to FIG. 8, a detailed explanation thereof is not repeated herein.

As compared to the exemplary embodiment described above with reference to FIG. 8, the photodiode 810′ exposed to illumination according to the present exemplary embodiment is not connected to the second row select signal line 811. Rather, the anode of the photodiode 810′ is connected to a bias voltage Vp. In the present exemplary embodiment, the photodiode 810′ may be an organic photodiode or another non-silicon type of photodiode off chip.

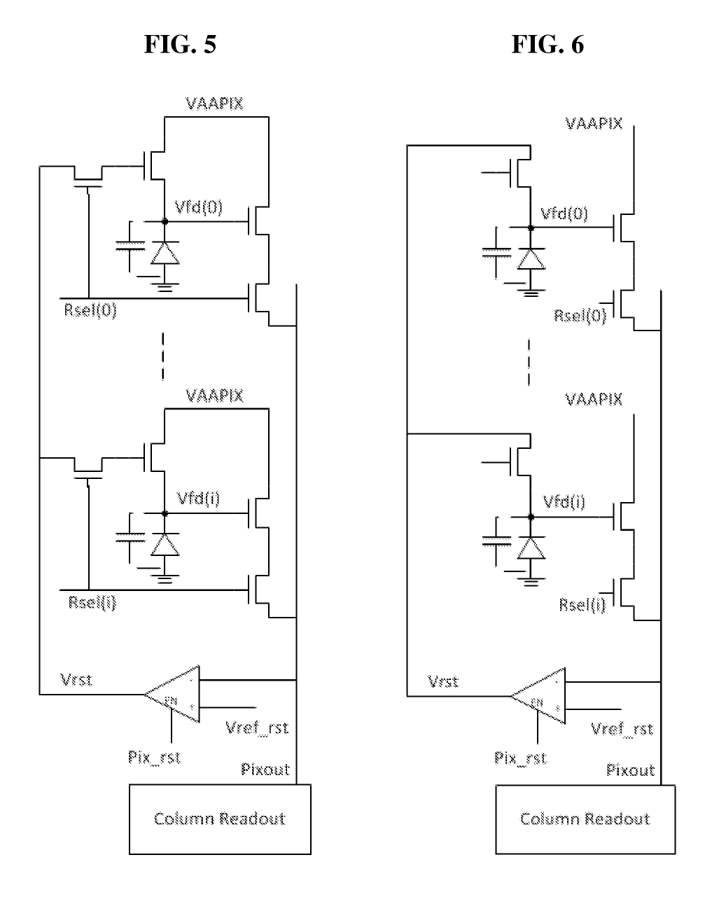

Meanwhile, the capacitor 820′ according to the present exemplary embodiment is disposed such that a bottom plate of the capacitor 820′ is connected to the second row select signal line 811 through which the second row select signal Rsel_bar(i) is applied, and the top plate of the capacitor 820 is connected to the floating diffusion node 860. In this case, the offset from the capacitor 820′ is selectively added to the floating diffusion node 860 to control a pixel reset as described above with reference to FIG. 5. Accordingly, the second row select signal Rsel_bar(i) applied via the second row select signal line 811 prevents the non-selected pixels from being reset even when the reset gate voltage is high (i.e., if the voltage Vfd is greater than or equal to the reset gate voltage Vrst, no reset will occur). Thus, the active pixel 80′ according to the present exemplary embodiment does not require an additional transistor to control a reset thereof.

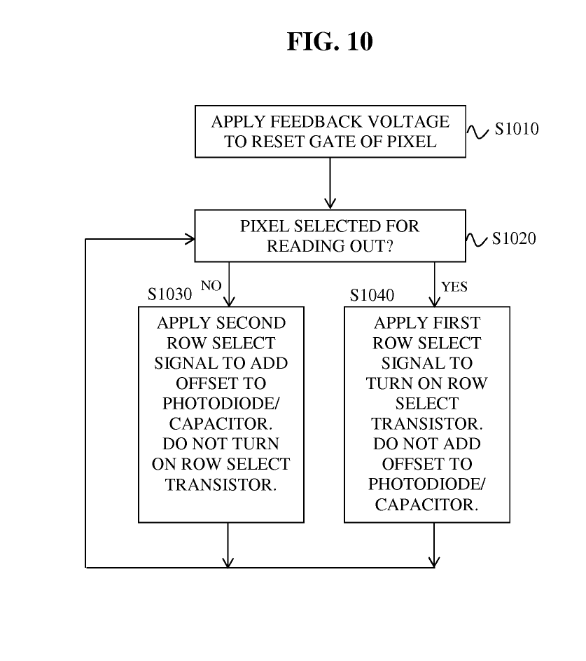

FIG. 10 is a flowchart of an image sensing method according to an exemplary embodiment. For example, the image sensing method may be implemented with respect to the imaging sensor described above with reference to FIGS. 8 and 9. Referring to FIG. 10, in operation S1010, a feedback voltage is applied to a gate terminal of a reset transistor of a pixel implementing pseudo-CDS. In operation 1020, it is determined whether the pixel is selected for reading out.

If the pixel is not selected for reading out (No at operation S1020), a first row select signal is applied to a gate terminal of a row select transistor to turn off the row select transistor, and a second row select signal is applied, e.g., to a capacitor, to add an offset to a photodiode of the pixel in operation S1030 to prevent a reset of the pixel. In this case, the first row select signal may have a high state, while the second row select signal may have a low state. For example, the second row select signal may be generated as an inverse of the first row select signal.

Meanwhile, if the pixel is selected for reading out (Yes at operation S1020), the first row select signal is applied to a gate terminal of a row select transistor to turn on the row select transistor, and the second row select signal is applied to the capacitor to not add an offset to a photodiode of the pixel in operation S1040, thereby allowing the reset of the pixel due to the feedback voltage applied to the reset gate in operation S1010. In this case, the first row select signal may have a low state, while the second row select signal may have a high state.

As described above, in a related art pseudo-CDS readout of pixels of a CMOS image sensor, thermal noise is not reduced since thermal noise components of a signal voltage and a reset voltage in a pseudo-CDS readout are not correlated. However, according to exemplary embodiments, thermal noise is reduced by applying a feedback voltage to a reset gate of the pixel implementing pseudo-CDS. Furthermore, to prevent an unintended reset of the pixel without increasing an area of the pixel (i.e., without requiring an additional transistor), an offset is selectively added to a photodiode of the pixel.

While not restricted thereto, an exemplary embodiment can be embodied as computer-readable code on a computer-readable recording medium. The computer-readable recording medium is any data storage device that can store data that can be thereafter read by a computer system, at least one processor, etc. Examples of the computer-readable recording medium include read-only memory (ROM), random-access memory (RAM), CD-ROMs, magnetic tapes, floppy disks, and optical data storage devices. The computer-readable recording medium can also be distributed over network-coupled computer systems so that the computer-readable code is stored and executed in a distributed fashion. Also, an exemplary embodiment may be written as a computer program transmitted over a computer-readable transmission medium, such as a carrier wave, and received and implemented in general-use or special-purpose digital computers that execute the programs.

Moreover, it is understood that in exemplary embodiments, one or more of the above-described components of the imaging device can include circuitry, a processor, a microprocessor, etc., and may execute a computer program stored in a computer-readable medium.

The foregoing exemplary embodiments are merely exemplary and are not to be construed as limiting the present invention. The present teaching can be readily applied to other types of devices. Also, the description of exemplary embodiments is intended to be illustrative, and not to limit the scope of the claims, and many alternatives, modifications, and variations will be apparent to those skilled in the art.

What is claimed is:

1. An imaging device implementing pseudo correlated double sampling (CDS) for pixel readouts, the imaging device comprising:
a pixel array comprising a pixel, the pixel comprising a reset transistor to control a reset of the pixel, a row select transistor to control a selection of the pixel to be read out, and a photodiode configured to generate a current in response to incident light;
a readout circuit configured to read out an output signal of the pixel, based on the detected incident light, via a pixel output line;
a feedback loop configured to receive a voltage from the pixel output line and to apply a reset gate voltage to a gate terminal of the reset transistor based on the received voltage; and
a controller configured to control an application of a row select signal to the row select transistor to select the pixel to be read out, and to selectively add an offset to the photodiode to prevent the pixel from being reset despite the reset gate voltage applied to the reset transistor.

2. The imaging device according to claim 1, wherein the pixel is a 3T pixel, or a pixel that uses a pseudo-CDS readout.

3. The imaging device according to claim 1, wherein the controller is configured to control an application of a signal, inverse to the row select signal, to the pixel to selectively add the offset to the photodiode.

4. The imaging device according to claim 3, wherein:
when the pixel is not selected to be read out, the controller is configured to apply the row select signal having a first state to turn off the row select transistor, and to apply the signal having a second state, inverse to the first state, to the pixel to prevent the pixel from being reset; and
when the pixel is selected to be read out, the controller is configured to apply the row select signal having the second state to turn on the row select transistor, and to apply the signal, having the first state, to the pixel to allow the pixel to be reset.

5. The imaging device according to claim 3, wherein:
the pixel further comprises a capacitor; and
the controller is configured to control the application of the signal, via a signal line, to a bottom plate of the capacitor to selectively add the offset to the photodiode.

6. The imaging device according to claim 5, wherein the capacitor is arranged parallel to the photodiode.

7. The imaging device according to claim 5, wherein:
the pixel further comprises a pixel output transistor and a node;
the photodiode is connected to a drain terminal of the reset transistor through the node and is connected to a gate terminal of the pixel output transistor via the node;
a source terminal of the reset transistor is connected to a reference voltage line; and
a drain terminal of the row select transistor is connected to a source terminal of the pixel output transistor, a gate terminal of the row select transistor is configured to receive the row select signal, and a source terminal of the row select transistor is connected to the pixel output line.

8. The imaging device according to claim 7, wherein a top plate of the capacitor is connected to the node, and the signal line is not connected to the photodiode.

9. The imaging device according to claim 1, wherein the row select transistor is connected to the feedback loop without an additional transistor between the feedback loop and the gate terminal of the row select transistor.

10. The imaging device according to claim 1, wherein:
the feedback loop comprises an operational amplifier comprising a first input terminal configured to receive a reference voltage and a second input terminal configured to receive the voltage from the pixel output line; and
the operational amplifier outputs the reset gate voltage according to a comparison between the reference voltage and the voltage from the pixel output line.

11. The imaging device according to claim 1, wherein the pixel array is a complementary metal-oxide-semiconductor (CMOS) image sensor pixel array.

12. A pixel of an imaging device, the pixel comprising:
a photodiode configured to generate a current in response to incident light;
a reset transistor configured to control a reset of the pixel; and
a row select transistor configured to control a selection of the pixel to be read out according to a row select signal and to output an output signal of the pixel, based on the incident light,
wherein a gate terminal of the reset transistor is configured to receive a reset gate voltage generated based on the output signal, and
wherein the gate terminal of the reset transistor receives the reset gate voltage without an additional transistor between the gate terminal of the reset transistor and a feedback point from which the pixel receives the reset gate voltage.

13. The pixel according to claim 12, wherein the pixel receives a signal to selectively add an offset to the photodiode to prevent the pixel from being reset despite the reset gate voltage applied to the gate terminal of the reset transistor.

14. The pixel according to claim 13, wherein the signal received by the pixel is inverse to the row select signal.

15. The pixel according to claim 13, further comprising a capacitor connected to a signal line to receive the signal for selectively adding the offset to the photodiode.

16. The pixel according to claim 15, further comprising:
a pixel output transistor connected to the reset transistor and the row select transistor; and
a node,
wherein the photodiode is connected to a drain terminal of the reset transistor through the node and is connected to a gate terminal of the pixel output transistor via the node,
a source terminal of the reset transistor is connected to a reference voltage line, and
a drain terminal of the row select transistor is connected to a source terminal of the pixel output transistor, and a gate terminal of the row select transistor is configured to receive the row select signal.

17. The pixel according to claim 16, wherein:
a bottom plate of the capacitor is connected to the signal line and a top plate of the capacitor is connected to the node; and
the photodiode is not connected to the signal line.

18. A control method of an imaging device implementing pseudo-CDS for pixel readouts, the method comprising:
controlling to apply a reset gate voltage to a gate terminal of a reset transistor, the reset gate voltage being based on a feedback from an output of a pixel comprising the reset transistor, a row select transistor, and a photodiode; and
controlling to selectively add an offset to the photodiode to prevent a reset of the pixel despite the reset gate voltage.

19. The control method according to claim 18, wherein the controlling comprises:
in response to the pixel not being selected for reading out, controlling to apply a first signal having a first state to a gate terminal of the row select transistor, and to apply a second signal having a second state, inverse to the first state, to the pixel to add the offset to the photodiode to prevent the reset of the pixel despite the reset gate voltage; and
in response to the pixel being selected for reading out, controlling to apply the first signal having the second state to the gate terminal of the row select transistor to turn on the row select transistor, and to apply the second signal having the first state to the pixel to allow the pixel to be reset.

20. A non-transitory computer readable recording medium having recorded thereon a program executable by a computer for performing the method of claim 18.
